(19) United States
(12) Patent Application Publication
(10) Pub. No.: US 2010/0167466 A1
(43) Pub. Date: Jul. 1, 2010

(54) SEMICONDUCTOR PACKAGE SUBSTRATE WITH METAL BUMPS

(76) Inventors: Ravikumar Adimula, Chandler, AZ (US); Myung Jin Yim, Chandler, AZ (US)

Correspondence Address: Gerbera/BSTZ;Blakely Sokoloff Taylor & Zafman LLP, 1279 OAKMEAD PARKWAY, SUNNYVALE, CA, 94085, US

(21) Appl. No.: 12/347,800

(22) Filed: Dec. 31, 2008

(51) Int. Cl. H01L 21/98; H05K 7/00; H05K 3/34; H05K 3/30

(52) U.S. Cl. 438/108; 174/257; 29/840; 29/832; 257/E21.705

(57) ABSTRACT

An apparatus and method of making a package substrate with metal bumps is presented. The package substrate comprises a substrate base and a plurality of metal bumps which are formed on the substrate base. A microelectronic die may thereafter be attached to the package substrate. Also presented is a method for attaching the package substrate to a printed circuit board (PCB).

### BACKGROUND OF THE INVENTION

1). Field of the Invention

Embodiments of this invention relate generally to semiconductor manufacturing. More specifically, embodiments of this invention relate to semiconductor package substrates.

2). Discussion of Related Art

Package substrates typically comprise of multiple layers and are generally flat. A microelectronic die is attached to the top surface of a package substrate—e.g., by flip chip technology. Before the die is attached to the package substrate, no interconnects exist for connecting the package substrate to a printed circuit board (PCB). After the microelectronic die is attached to the top layer of the substrate, the entire assembly is connected to a PCB by applying solder bumps to the bottom layer of the substrate and subjected it to solder reflow. Substrates used in MMAP packages, for example, commonly have solder bumps applied to their bottom side after the die is attached. The package substrate itself, which the die is attached to, does not include interconnects for attachment to a PCB, and thus requires solder bump attachment and reflow step during package manufacturing. Current BGA package manufacturing process involves attaching such solder bumps with solder reflow, and thus subjects the entire package to very high temperatures such as 260° C. Furthermore, the solder balls present reliability issues and can structurally degrade. The solder is low fatigue life material in the entire package structure.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is an illustration of a cross-sectional side view of a package substrate for a microelectronic die before a microelectronic die is attached to it, according to one embodiment of the invention;

FIG. 2 is an illustration of a bottom view of a package, according to one embodiment of the invention;

FIG. 3a is an illustration of a cross-sectional side view of a substrate base of a package substrate, according to one embodiment of the invention;

FIG. 3b is an illustration of a cross-sectional side view of a substrate base with a layer of polymer formed thereon, according to one embodiment of the invention;

FIG. 3c is an illustration of a view similar to FIG. 3b after trenches are formed within the polymer layer, according to one embodiment of the invention;

FIG. 3dis an illustration of a view similar to FIG. 3c after copper (Cu) is deposited within the trenches, according to one embodiment of the invention;

FIG. 3e is an illustration of a view similar to FIG. 3dafter a microelectronic die is attached to the package substrate on a side of the substrate base opposite of the plurality of conductive bumps, according to one embodiment of the invention.

FIG. 3f is an illustration of a view similar to FIG. 3e after a molding compound is deposited on the package substrate with the microelectronic die within the molding compound, according to one embodiment of the invention;

FIG. 3g is an illustration of a view similar to FIG. 3f after a polymer layer is removed from the substrate base, according to one embodiment of the invention;

FIG. 4a is an illustration of a cross-sectional side view of a microelectronic package comprising a package substrate, according to one embodiment of the invention.

FIG. 4b is an illustration of a cross-sectional side view of a PCB, according to one embodiment of the invention;

FIG. 4c is an illustration of a cross-sectional side view of a substrate base of a package substrate attached to a PCB, according to one embodiment of the invention.

FIG. 5a is an illustration of a cross-sectional side view of a microelectronic package comprising a package substrate with adhesive formed thereon, according to one embodiment of the invention;

FIG. 5b is an illustration of a cross-sectional side view of a PCB, according to one embodiment of the invention;

FIG. 5c is an illustration of a cross-sectional side view of an adhesive layer between a substrate base of a package substrate and PCB, according to one embodiment of the invention; and

FIG. 5d is an illustration of a cross-sectional side view of a substrate base of a package substrate attached to a PCB, according to one embodiment of the invention.

It will be appreciated that for simplicity and clarity of illustration, elements illustrated in the figures have not necessarily been drawn to scale. For example, the dimensions of some of the elements may be exaggerated relative to other elements for clarity. Further, where considered appropriate, reference numerals have been repeated among the figures to indicate corresponding or analogous elements.

### DETAILED DESCRIPTION OF THE INVENTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

A package substrate is presented which comprises a substrate base and a plurality of conductive bumps formed thereon. A microelectronic die is then attached to the entire package substrate, specifically on the substrate base opposite the plurality of conductive bumps. The plurality of conductive bumps may thereafter be used for attachment to contacts of a printed circuit board (PCB).

It should be understood that the terms “bottom side” and “top side” are relative terms based on the bottom top of the illustrated figures and used to provide an orientation for explanatory purposes.

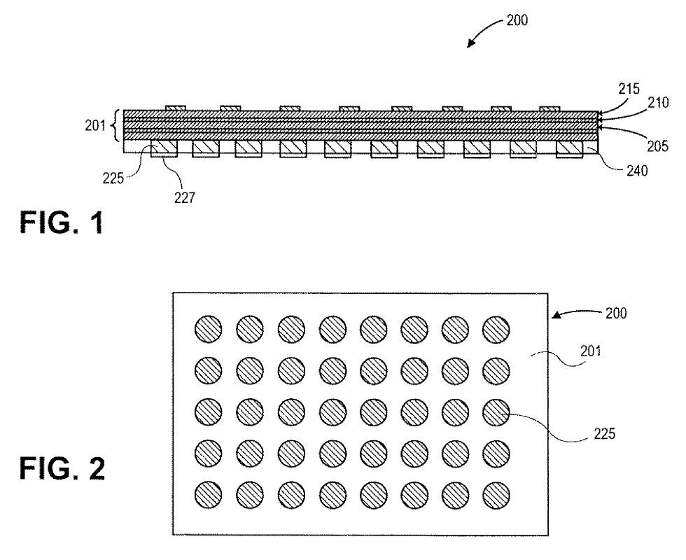

FIG. 1 is illustrates a package substrate for a microelectronic die, before the microelectronic die is attached to it, according to one embodiment of the invention. Package substrate 200 is shown comprising a substrate base 201 and a plurality of conductive bumps 225 formed on a bottom side of the substrate base 201.

Substrate base 201 may comprise a variety of layers—e.g., top solder mask 215; a layer of copper traces 210 formed on top of a bismaleimide-triazine (BT) core layer 205; and contact pads 203 formed on the top surface. Other layers may be included within the substrate base—e.g., bottom solder mask on the opposite side of the top solder mask, metal trace layers on the bottom side of the BT core to allow for routing of the conductive bumps 225 to the opposite side of the substrate, etc. While the layers are shown as one solid continuous layer for illustrative purposes, it should be understood that not all layers are continuous. For example, the layer of copper traces 210 are not one solid continuous layer but rather a layer of various traces connecting to different contacts formed on the surface of the substrate base.

When vias are formed within the substrate, it allows various contact pads on the top side of the substrate base to be routed to the opposite side of the substrate base and to various conductive bumps of the plurality of conductive bumps 225. A microelectronic die attaches to the contacts on the side opposite the plurality of conductive bumps—e.g., by wire bonding or C4 flip chip—and is then electrically coupled to the plurality of conductive bumps 225, as well as to a PCB when the package substrate is attached to a PCB. The plurality of conductive bumps 225 are formed on the bottom side of substrate 200 and may be used to attach the package substrate 200 to the PCB.

In one embodiment the conductive bumps 225 are comprised of copper (Cu) or alloys thereof. The Cu alloys may include, for example, aluminum (Al), nickel (Ni), or gold (Au). In one embodiment, the plurality of Cu bumps are plated (e.g., electroplated) with capping layers 227 of Al, Ni, Au, or alloys thereof, to protect the Cu bumps from oxidation. The capping layers 227 are of sufficient thickness to prevent such oxidation. The entire Cu bump may be capped or only a portion of the Cu bump—e.g., the end of the Cu bump.

It should be understood that the conductive bumps presented in the detailed description are more than mere conductive pads. The conductive bumps have a preferred height within a range of 25 to 100 microns—e.g., 50 microns. In one embodiment, the conductive bumps are conductive pillars. In yet another embodiment, the conductive bumps are Cu pillars of about 50 microns in height.

Moreover, it should be noted that other methods of attaching the plurality of conductive bumps 225 to the substrate base 201 may be used to create the package substrate without compromising the underlying principles presented herein.

Package substrate 200 also includes a polymer layer 240 formed on the bottom side of the substrate base 201. Each bump of the plurality of conductive bumps 225 extends through the polymer layer 240. In one embodiment, the polymer layer 240 is not present—e.g., removed before the microelectronic die is attached, or alternatively, not used at all.

FIG. 2 illustrates a bottom view of package 200, according to one embodiment of the invention. Conductive bumps 225 are shown projected from the bottom of substrate base 201.

Manufacturing a Package Substrate and Attaching a Microelectronic Die to the Package Substrate

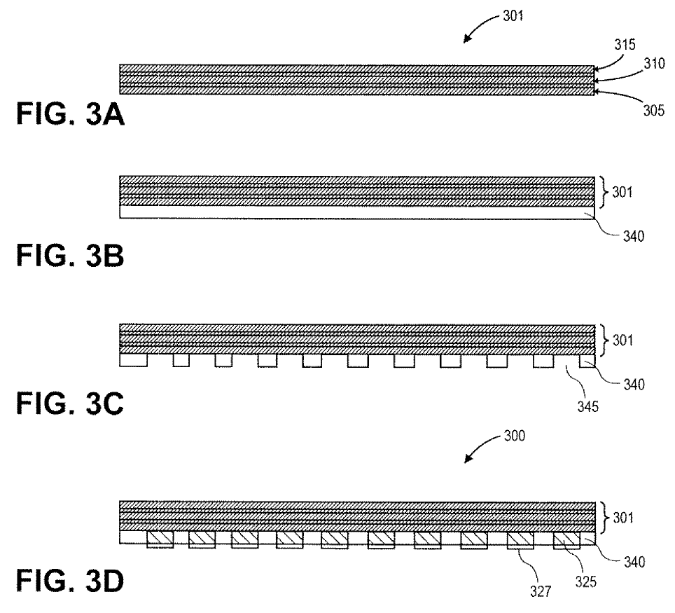

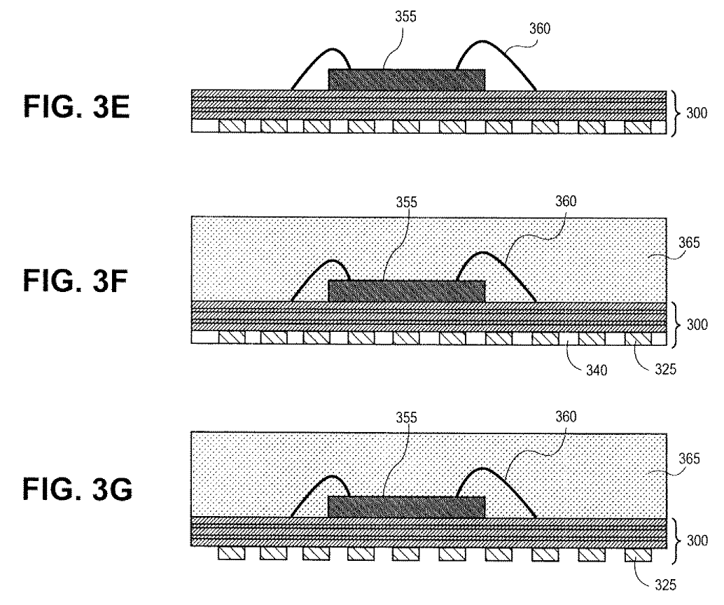

FIGS. 3a-g illustrate example methods of making a substrate including conductive bumps, as well as attaching a microelectronic die to such a package substrate. The package substrate may be used in, for example, a MMAP package, and further does not require a change to the manufacturing process of the MMAP package.

FIG. 3a illustrates a substrate base 301 of a package substrate 300 before having a plurality of conductive bumps attached to one side of the substrate base 301. In the embodiment shown, substrate base 301 is shown comprising copper trace layer 310 formed on top of a BT core layer 305, and a top solder mask 315 formed on top of the copper trace layer 310. Again, substrate base 201 may comprise a variety of layers without compromising the underling principles presented herein.

As shown in FIG. 3b, a polymer layer 340 is formed on the bottom side of the substrate. The layer may be formed by, for example, spin coating or lamination process of the polymer on the bottom side of the substrate base. The polymer layer 340 is of sufficient thickness to allow for the conductive bumps 325 to be formed therein. The polymer layer may be, for example, an epoxy film layer for being used as polymer layer after metal bump formation, or a photo-resist layer for being removed after metal bump formation.

As shown in FIG. 3c, trenches 345 are formed within the polymer layer 340. The polymer layer 340 may be etched, for example, to form trenches 345. In one embodiment, trenches 345 extend all the way to substrate base 301 and allow the conductive bumps to couple to metal traces which allow for routing to the other side of the substrate.

As shown in FIG. 3d, conductive material 350 (e.g., Cu) is deposited within the trenches 345 to form a plurality of conductive bumps 325. The substrate base 301 and plurality of conductive bumps 325 comprise the package substrate 300.

In one embodiment, the conductive material is deposited by electroplating. The conductive material may be comprised of, for example, copper (Cu) or alloys thereof. The Cu alloys may include, for example, Cu along with aluminum (Al), nickel (Ni), or gold (Au). In one embodiment, the plurality of Cu bumps are plated (e.g., electroplated) with capping layers 327 of Al, Ni, Au, or alloys thereof. The entire Cu bump may be capped—which would require the polymer layer to be removed first—or only a portion of the Cu bump may be capped—e.g., only the end of the Cu bump.

The conductive bumps 325 may have a preferred height within a range of 25 to 100 microns—e.g., 50 microns. In one embodiment the conductive bumps 325 are Cu and pillar shaped.

As shown in FIG. 3e, after forming the plurality of conductive bumps 325 on the substrate base 301, a microelectronic die 355 is attached to package substrate 300. In the embodiment shown, wire bonding is used to couple the microelectronic die 355 to contact pads on the top surface of the substrate base 301 opposite the plurality of conductive bumps.

The microelectronic die 355 may also be attached by other processes without compromising the underlying principles presented herein. For example, the die may be attached using C4 flip chip technology where solder bumps on the die would align with, and contact, the contact pads on the top surface of the substrate base 301.

FIG. 3f illustrates a molding compound 365 formed over the top surface of the substrate base 301 of substrate 300, encapsulating the microelectronic die 355. The molding compound provides, for example, protection of the microelectronic die 355 and bonding wires 360.

As illustrated in FIG. 3g, polymer layer 340 is then removed from the substrate base 301. The polymer layer 340 may be removed by various processes, for example, stripping off by chemical solution. Alternatively, in another embodiment, the polymer layer 340 is removed before the die 355 is attached to the substrate base 301 by the same method.

Attaching a Package Substrate to a Printed Circuit Board (PCB)

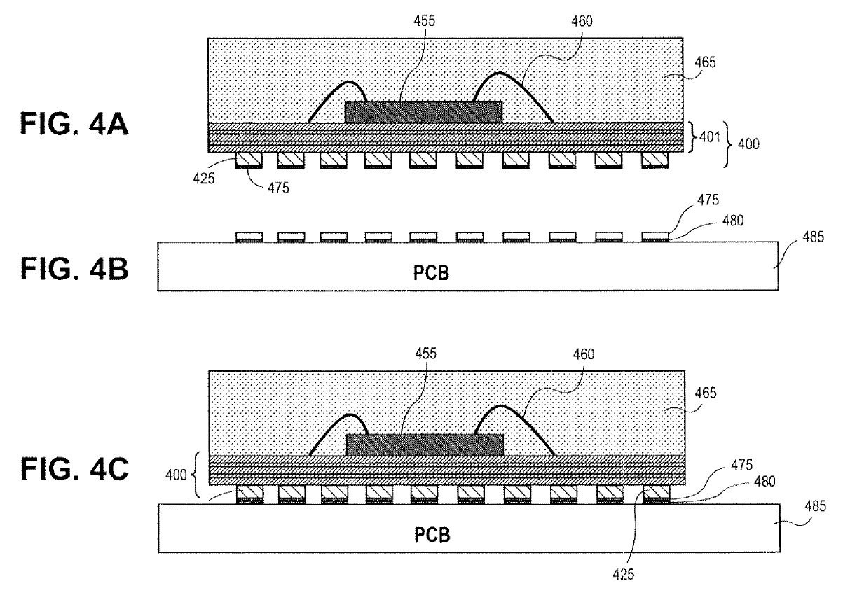

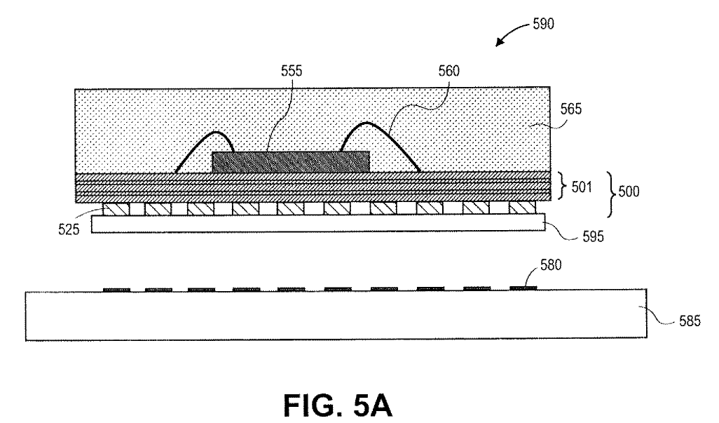

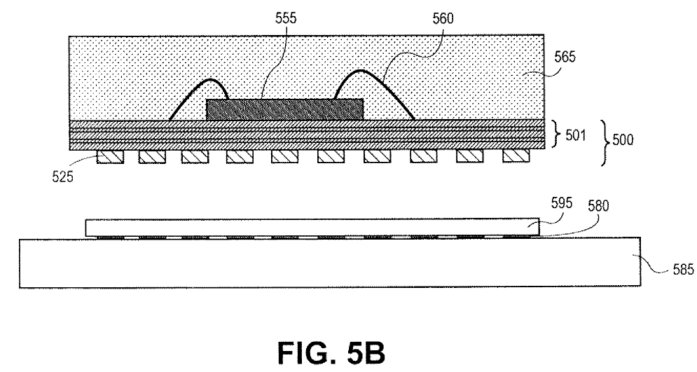

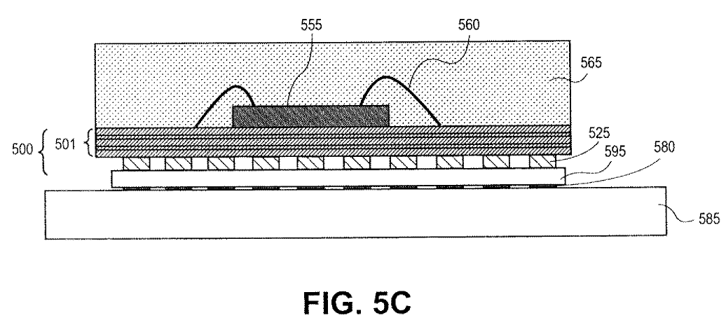

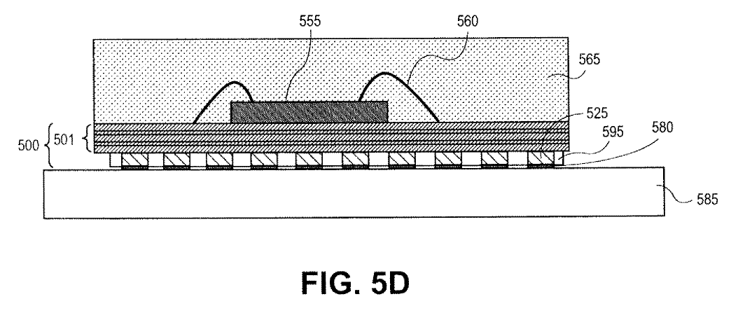

FIGS. 4a-c and FIGS. 5a-e illustrate example methods of attaching the substrate to a PCB. Including the plurality of conductive bumps 225 as part of the substrate 200 allows the solder bump attachment and reflow step during package manufacture to be eliminated if desired.

Temperature may be a critical factor in promoting damage to the microelectronic assembly in some instances. If high temperature is not concern, solder reflow may be used to attach the substrate to the PCB, as shown in the example method of FIGS. 4a-c. Solder reflow may occur, for example, at temperatures greater than 150° C. Typical solder reflow peak temperatures may, for example, vary from 180° C. to 260° C. depending on the solder composition.

If high temperature is a concern, an electrically conductive adhesive can be used instead, which enables electrical and mechanical connections at temperatures well below, for example, 150° C. An example method of using adhesives to attach the package substrate to the PCB is illustrated in FIGS. 5a-e. Using the adhesive along with an underfill function may function together to significantly improve board level reliability. Further, compared to existing LGA packages, for example, lower resistant joints can be achieved. There will also be reduced concern for package co planarity.

FIGS. 4a-c illustrates a method of attaching a package substrate to contacts of a PCB by using solder, according to one embodiment of the invention. The solder material is deposited between the plurality of conductive bumps and the PCB and thereafter reflowed.

FIG. 4a illustrates a microelectronic package 490, before being attached to contacts on a PCB, according to one embodiment of the invention. The microelectronic package 490 may be manufactured as described above in FIGS. 3a-f and corresponding description may apply. The microelectronic package 490 in FIG. 4a is shown comprising a package substrate 400, microelectronic die 455, and molding compound 465. As shown, after the microelectronic package 490 is assembled, solder material 475 is deposited on the ends of the plurality of conductive bumps 425 to cap the bumps 425 with solder. The solder caps may be formed by, for example, dipping the plurality of conductive bumps 425 within solder material 475. Solder material 475 may comprise, for example, silver (Ag), tin (Sn), lead (Pb), or alloys thereof—e.g., AgSn, PbSn, SnAgCu, SnAgBi, AuSn, In and InSn.

Alternatively, in another embodiment, solder material 475 is deposited on contacts 480 of PCB 485, as shown in FIG. 4b. Contacts 480 are formed on PCB 485 and subsequently solder material 475 are deposited on contacts 480. The contacts 480 are to align with the plurality of conductive bumps 425 and used to attach the package 490 and PCB 485. In yet another embodiment, solder material 475 is deposited on both the ends of the plurality of conductive bumps 425 and on the contacts 480 of PCB 485.

FIG. 4c illustrates the substrate 400 attached to the PCB with the solder material 475 deposited between. The plurality of conductive bumps 425 are coupled to the contacts 480 of the PCB 485 with the solder material 475 in between. The combination of the package 490 and PCB 485 may then be heated to melt the solder material 475 and thereafter cooled to solidify the solder material 475. The solder reflow

FIGS. 5a-c illustrates a method of attaching a package substrate to contacts of a PCB by using adhesive, according to one embodiment of the invention. As shown in FIG. 5a, in one embodiment, adhesive 595 are formed on microelectronic package 590 before attached to contacts 580 on a PCB 585. The microelectronic package 590 may be manufactured as described above in FIGS. 3a-f and corresponding description may apply. The microelectronic package 590 comprises a package substrate 500, microelectronic die 555, and molding compound 565. As shown, adhesive layer 495 is formed across the ends of the plurality of conductive bumps 525.

Alternatively, in one embodiment, the adhesive layer 595 is formed on contacts 580 of PCB 585, as shown in FIG. 5b. Contacts 580 are formed on PCB 585 and subsequently adhesive layer 495 is deposited on the side of PCB 585 with contacts 480 formed on it. In one embodiment, the adhesive layer 595 is deposited on PCB 585 only where the contacts 580 are formed.

In one embodiment, adhesive layer 495 is an anisotropic conductive film or paste (e.g., epoxy). The anisotropic conductive film allows for conductivity in one direction, allowing conductivity between the conductive bumps 425 and contacts 580 on the PCB; however, conductivity is not allowed in the direction between conductive bumps 425, preventing shorting of the conductive bumps. In another embodiment, adhesive layer 495 is a non-conductive film or paste which assists in attachment of the substrate 500 to PCB 585. In yet another embodiment, an adhesive layer 495 is formed on both the plurality of bumps 525 and contacts 580 of the PCB 585.

FIG. 5c illustrates the adhesive layer 595 between the plurality of conductive bumps 525 and contacts 580. Pressure is applied so that the conductive bumps 525 are pressed into the adhesive layer 595 to couple to the contacts 580 of the PCB 485, as shown in FIG. 5d. In the embodiment shown, bumps 525 are pressed through the adhesive layer 595 and contact the contacts 580.

If the adhesive layer 595 is an anisotropically conductive material then the bumps 525 may contact the contacts 580, or be left with conductive adhesive in between it and the contacts 580 so that the conductive fillers in the anisotropically conductive material connects between the bump 525 and the contact 580. If a non-conductive adhesive material is used, then bumps 525 are pressed through the adhesive layer 595 and contact the contacts 580. The adhesive layer is then cured.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A package substrate to be attached to a microelectronic die, the package substrate comprising:
a substrate base; and
a plurality of copper (Cu) bumps formed on a first side of the substrate base, wherein a second side of the substrate is to be attached to a microelectronic die, the second side of the substrate opposite the first side.

2. The package substrate of claim 1, wherein the plurality of Cu bumps are pillar-shaped.

3. The package substrate of claim 1, wherein the plurality of Cu bumps further comprises at least one metal selected from the group consisting of aluminum, nickel, gold, and alloys thereof.

4. The package substrate of claim 3, wherein the at least one metal is electroplated on the plurality of Cu bumps.

5. The package substrate of claim 1, further comprising:
a capping layer formed on an end of each bump of the plurality of Cu bumps.

6. The package substrate of claim 1, wherein a height of the plurality of Cu bumps is within a range of 25 to 100 microns.

7. The package substrate of claim 1, further comprising:
a polymer layer.

8. A method of making a microelectronic package including a package substrate and a microelectronic die, the method comprising:
forming a substrate base;
forming a plurality of copper (Cu) bumps on a first side of the substrate base, wherein the package substrate comprises the plurality of Cu bumps and substrate base; and
after forming the plurality of Cu bumps on the substrate base, attaching a microelectronic die to a second side of the substrate base, the second side opposite the first side of the substrate base.

9. The method of claim 8, wherein the forming of the plurality of Cu bumps comprises:
forming a polymer layer on the first side of a substrate;
forming a plurality of trenches within the polymer layer, the trenches extending to the substrate base; and
depositing a conductive material comprising Cu within the plurality of trenches to form the plurality of Cu bumps.

10. The method of claim 9, wherein the depositing of conductive material within the plurality of trenches is by electroplating.

11. The method of claim 9, wherein the conductive material further comprises at least one metal selected from the group consisting of aluminum, nickel, gold, and alloys thereof.

12. The method of claim 9, further comprising:
plating at least one metal on at least a portion of each bump of the plurality of Cu bumps, the at least one metal selected from the group consisting of aluminum, nickel, gold, and alloys thereof.

13. The method of claim 9, further comprising:
depositing a molding compound on the second side of the substrate base, the microelectronic die within the molding compound; and
removing the polymer layer to expose the plurality of Cu bumps.

14. The method of claim 13, further comprising:
forming a capping layer of solder on an end of each bump of the plurality of Cu bumps.

15. The package substrate of claim 14, wherein the capping layer of solder is a metal alloy and comprised of at least one combination of metals selected from the group consisting of AgSn, PbSn, SnAgCu, SnAgBi, AuSn, In and InSn.

16. The method of claim 8, wherein a height of the plurality of Cu bumps is within a range of 25 to 100 microns.

17. The method of attaching a package substrate to contacts on a printed circuit board (PCB), the method comprising:
depositing a solder material between the contacts on the PCB and a plurality of copper (Cu) bumps formed on a first side of a substrate base, wherein the package substrate is comprised of the plurality of Cu bumps and substrate base; and
attaching the package substrate to the contacts of the PCB so that ends of the plurality of Cu bumps are connected to the contacts of the PCB with the deposit material between.

18. The method of 17, wherein the solder material is deposited on the ends of the plurality of Cu bumps.

19. The method of 17, wherein the solder material is deposited on the contacts of the PCB.

20. The method of 17, wherein the solder material is deposited on the contacts of the PCB and on the ends of the plurality of Cu bumps.

21. The method of claim 17, wherein the attaching of the package substrate to the contacts of the PCB comprises:
heating the solder material to a temperature greater than 150° C. so that the solder material melts; and
cooling the solder material so that the solder material solidifies.

22. The method of claim 17, wherein a height of the plurality of Cu bumps is within a range of 25 to 100 microns.

23. The method of attaching a package substrate to contacts of a printed circuit board (PCB), the method comprising:
forming an adhesive layer between the contacts of the PCB and a plurality of copper (Cu) bumps formed on a first side a substrate base, wherein the package substrate comprises the plurality of Cu bumps and substrate base; and
applying pressure to the package substrate and PCB so that an end of each Cu bump is pressed into the adhesive layer and coupling to the contacts of the PCB.

24. The method of claim 23, further comprising:
curing the adhesive layer.

25. The method of claim 23, wherein the adhesive layer is an anisotropic conductive film or paste.

26. The method of claim 23, wherein the adhesive layer is a non-conductive film or paste.

27. The method of claim 23, wherein the adhesive layer is formed on the contacts of the PCB.

28. The method of claim 23, wherein the adhesive layer is formed on the end of each Cu bump.

29. The method of claim 23, wherein the adhesive layer is formed on the contacts of the PCB and on the end of each Cu bump.

30. The method of claim 23, wherein a height of the plurality of Cu bumps is within a range of 25 to 100 microns.
